(19) United States
(12) Patent Application Publication
(10) Pub. No.: US 2014/0060887 A1
(43) Pub. Date: Mar. 6, 2014

(54) TRANSPARENT ELECTRIC CONDUCTOR

(71) Applicants: Laura Jane Singh, Paris (FR); David Nicolas, Paris (FR); Toyohiro Chikyow, Ibaraki (JP); Seunghwan Park, Shanghai (CN); Naoto Umezawa, Ibaraki (JP)

(72) Inventors: Laura Jane Singh, Paris (FR); David Nicolas, Paris (FR); Toyohiro Chikyow, Ibaraki (JP); Seunghwan Park, Shanghai (CN); Naoto Umezawa, Ibaraki (JP)

(73) Assignees: NATIONAL INSTITUTE FOR MATERIALS SCIENCE, Tsukuba-shi,Ibaraki (JP); SAINT-GOBAIN GLASS FRANCE, Courbevoie (FR)

(21) Appl. No.: 14/113,774

(22) PCT Filed: Apr. 26, 2012
(86) PCT No.: PCT/EP2012/057661

§ 371 Date: Nov. 18, 2013

(30) Foreign Application Priority Data
Apr. 28, 2011 (FR) 1153653

(51) Int. Cl. H01B 1/08; H01B 13/00

(52) U.S. Cl. CPC H01B 1/08; H01B 13/0036
USPC 174/126.1; 427/126.3

(57) ABSTRACT

A transparent electric conductor includes titanium oxide doped with aluminum and at least one other dopant:
either in the form Ti_{1-a-b}AlₐX_{b}O_{y}, where X is a dopant or a mixture of dopants selected from the group consisting of Nb, Ta, W, Mo, V, Cr, Fe, Zr, Co, Sn, Mn, Er, Ni, Cu, Zn and Sc, a is in the range 0.01 to 0.50, and b is in the range 0.01 to 0.15;
or in the form Ti₁₋ₐAlₐF_{c}O_{y-c}, where a is in the range 0.01 to 0.50, and c is in the range 0.01 to 0.10.

With the above composition, the electrical conductivity and the light transmittance are suitable for use of the transparent electric conductor in various applications, in particular as a transparent electrode of an electronic device.

The present invention relates to a transparent electric conductor and to an electrode and a device comprising such a transparent electric conductor. The invention also relates to a process for manufacturing a transparent electric conductor.

Due to an increasing demand for devices such as photovoltaic devices, flat-panel display devices or light-emitting devices, the industrial use of transparent conductive oxides (TCO) has undergone a major expansion. In particular, zinc oxide doped with aluminum (AZO) is a well known TCO material having a low electrical resistivity and high visible light transmittance, widely used as an electrode for photovoltaic devices. However, AZO has the disadvantage of having a relatively low refractive index so that, when it is located at certain positions in a photovoltaic device, it tends to reflect significant amounts of incident radiation away from the active semiconductor material, thereby reducing the efficiency of the photovoltaic device.

Titanium oxide doped with niobium (Nb) or tantalum (Ta) is another TCO material which is advantageous in that it has a relatively low electrical resistivity and a relatively high refractive index. However, due to the presence of the dopant, titanium oxide doped with niobium or tantalum has a relatively high visible light absorption, as well as large variance in the light transmittance over the visible light range, which limits its use in devices such as photovoltaic devices. In this respect, APPLIED PHYSICS LETTERS 86, 252101 (2005), Y. Furubayashi, T. Hitosugi, Y. Yamamoto, K. Inaba, Go Kinoda, Y. Hirose, T. Shimada, and T. Hasegawa, “A transparent metal: Nb-doped anatase TiO₂”, shows that the inclination of the light transmittance spectrum of titanium oxide TiO₂ doped with niobium Nb gets steeper as the concentration of Nb in TiO₂ increases.

It is these drawbacks that the invention intends more particularly to remedy by proposing a transparent electric conductor which simultaneously exhibits a low electrical resistivity, a low visible light absorption, relatively flat light absorbing characteristics over the visible light range and a high refractive index.

For this purpose, one subject of the invention is a transparent electric conductor (or TCO) comprising titanium oxide doped with aluminum and at least one other dopant:
either in the form Ti_{1-a-b}AlₐX_{b}O_{y}, where X is a dopant or a mixture of dopants selected from the group consisting of Nb, Ta, W, Mo, V, Cr, Fe, Zr, Co, Sn, Mn, Er, Ni, Cu, Zn and Sc, a is in the range 0.01 to 0.50, and b is in the range 0.01 to 0.15;
or in the form Ti₁₋ₐAlₐF_{c}O_{y-c}, where a is in the range 0.01 to 0.50, and c is in the range 0.01 to 0.10.

According to an advantageous feature, the value of a in the composition formula Ti_{1-a-b}AlₐX_{b}O_{y} or in the composition formula Ti₁₋ₐAlₐF_{c}O_{y-c} of the transparent electric conductor is in the range 0.02 to 0.15, preferably in the range 0.03 to 0.12.

Preferably, in the composition formula Ti_{1-a-b}AlₐX_{b}O_{y} of the transparent electric conductor, X is Nb, Ta, W or Mo.

According to an advantageous feature, in the composition formula Ti_{1-a-b}AlₐX_{b}O_{y} of the transparent electric conductor, X is Nb, Ta, W or Mo, a is in the range 0.01 to 0.50, preferably in the range 0.02 to 0.15, even more preferably in the range 0.03 to 0.12, and b is in the range 0.01 to 0.15, preferably in the range 0.03 to 0.12, even more preferably in the range 0.05 to 0.12.

According to an advantageous feature, in the composition formula Ti_{1-a-b}AlₐX_{b}O_{y} of the transparent electric conductor, X is Nb with a in the range 0.02 to 0.12, preferably in the range 0.04 to 0.08, and b in the range 0.03 to 0.12, preferably in the range 0.05 to 0.12.

Of course, all possible combinations of the initial, preferred and much preferred ranges listed in the above paragraphs for the a and b values are envisaged and should be considered as described in the context of the present invention.

The transparent electric conductor comprising Ti_{1-a-b} AlₐX_{b}O_{y} or Ti₁₋ₐAlₐF_{c}O_{y-c} may further comprise Si or Ge or Sn as a substitutional atom of Al.

According to an advantageous feature, the electrical resistivity of the transparent electric conductor is at most 10⁻² Ωcm, preferably at most 3×10⁻³ Ωcm.

According to an advantageous feature, the refractive index of the transparent electric conductor is at least 2.15 at 550 nm, preferably at least 2.3 at 550 nm.

According to an advantageous feature, the light transmittance flatness index of the transparent electric conductor is within the range 1±0.066.

Within the meaning of the invention, the light transmittance flatness index, denoted r, is a thickness-invariant parameter, which is determined in the following manner:
first, the regression line y=ax+b of the set of points {λⱼ, Ln(Tⱼ)}_{0≦j≦n} is obtained, by means of a least mean square approximation, where (λⱼ)_{0≦j≦n} are wavelength values within the wavelength range 400 nm to 700 nm, and (Tⱼ)_{0≦j≦n} are the light transmittance values of the transparent electric conductor measured at each of the wavelengths (λⱼ)_{0≦j≦n};
then, the light transmittance flatness index r is defined as the ratio

$$r = \frac{{y}_{λ = 400 nm}}{{y}_{λ = 700 nm}} .$$

Since the light transmittance is an exponential function of the thickness of the sample under measurement, the ratio between the two logarithmic values in the above definition of the flatness index r cancels the dependency on the thickness of the sample, and thus the flatness index r is a thickness-invariant parameter.

According to an advantageous feature, the transparent electric conductor is in the form of a film having a thickness of at most 1 micrometer. Within the meaning of the invention, a film is a layer of material, which may be a monolayer or a multilayer.

According to an advantageous feature, the light transmittance, in the wavelength range 400 nm to 700 nm, of the transparent electric conductor in the form of a film having a thickness of 100 nm is at least 70%, preferably at least 75%. Throughout this description, light transmittance data are determined according to the standard ISO 9050:2003.

Another subject of the invention is an electrode comprising a transparent electric conductor as described above, in the form of a film.

This electrode may be used in an electronic device. Within the meaning of the invention, an electronic device is a device that comprises a functional element including an active part and two electrically conductive contacts, also called electrodes, on both sides of the active part. The electrode according to the invention may be used, in particular, in a photovoltaic device, the active part of which is able to convert the energy originating from a radiation into electrical energy; an electrochromic device, the active part of which is able to switch reversibly between a first state and a second state having optical and/or energy transmission properties different from the first state; a light-emitting device, in particular an organic light-emitting diode (OLED) device, the active part of which is able to convert electrical energy into radiation; a flat-panel display device; an image sensing device, the active part of which is able to convert an optical image into an electrical signal.

Another subject of the invention is a device, such as a photovoltaic device, an electrochromic device, a light-emitting device, a flat-panel display, an image sensing device, an infrared-reflective glazing, an UV-reflective glazing or an antistatic glazing, wherein the device comprises a transparent electric conductor as described above, in the form of a film.

Another subject of the invention is a process for manufacturing a transparent electric conductor, comprising a step of forming on a surface, in particular the surface of a substrate, a film of Ti_{1-a-b}AlₐX_{b}O_{y}, where X is a dopant or a mixture of dopants selected from the group consisting of Nb, Ta, W, Mo, V, Cr, Fe, Zr, Co, Sn, Mn, Er, Ni, Cu, Zn and Sc, in such a way that a is in the range 0.01 to 0.50, preferably in the range 0.02 to 0.15, even more preferably in the range 0.03 to 0.12, and b is in the range 0.01 to 0.15.

Another subject of the invention is a process for manufacturing a transparent electric conductor, comprising a step of forming on a surface, in particular the surface of a substrate, a film of Ti₁₋ₐAlₐF_{c}O_{y-c}, in such a way that a is in the range 0.01 to 0.50, preferably in the range 0.02 to 0.15, even more preferably in the range 0.03 to 0.12, and c is in the range 0.01 to 0.10.

According to an advantageous feature, in the first process mentioned above, X is Nb, Ta, W or Mo, a is in the range 0.01 to 0.50, preferably in the range 0.02 to 0.15, even more preferably in the range 0.03 to 0.12, and b is in the range 0.01 to 0.15, preferably in the range 0.03 to 0.12, even more preferably in the range 0.05 to 0.12.

According to an advantageous feature, in the first process mentioned above, X is Nb, a is in the range 0.02 to 0.12, preferably in the range 0.04 to 0.08, and b is in the range 0.03 to 0.12, preferably in the range 0.05 to 0.12.

Of course, all possible combinations of the initial, preferred and much preferred ranges listed in the above paragraphs for the a and b values are envisaged and should be considered as described in the context of the present invention.

In any one of the above-mentioned processes, the temperature of the surface at the time of forming the film on the surface may be room temperature. As a variant, in any one of the above-mentioned processes, the temperature of the surface at the time of forming the film on the surface may be in the range 100° C. to 450° C.

In any one of the above-mentioned processes, following the step of forming the film, the process may comprise a step of annealing the film in a reducing atmosphere. The reducing atmosphere may contain H₂ and the step of annealing may be performed at a temperature in the range 350° C. to 700° C.

The features and advantages of the invention will appear in the following description of several exemplary embodiments of a transparent electric conductor according to the invention, given solely by way of example and made with reference to the appended drawings in which:

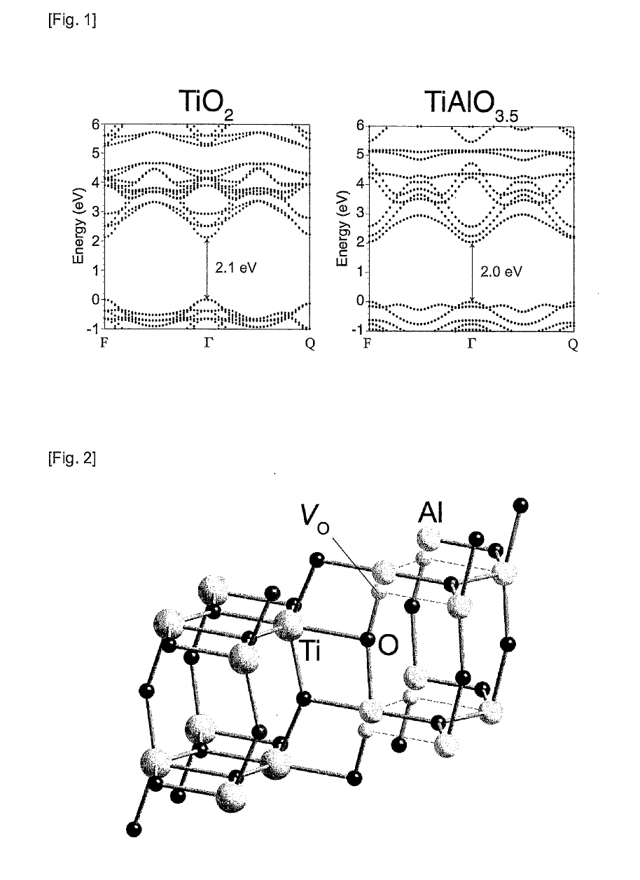

FIG. 1 is a diagram showing the energy band structures of TiO₂ and TiAlO_{3.5} obtained according to first-principle calculations;

FIG. 2 is a TiAlO_{3.5} model used in the first-principle calculations, wherein a TiO₂:Al₂O₃ ratio of 50:50 was used and Vₒ represents an oxygen vacancy;

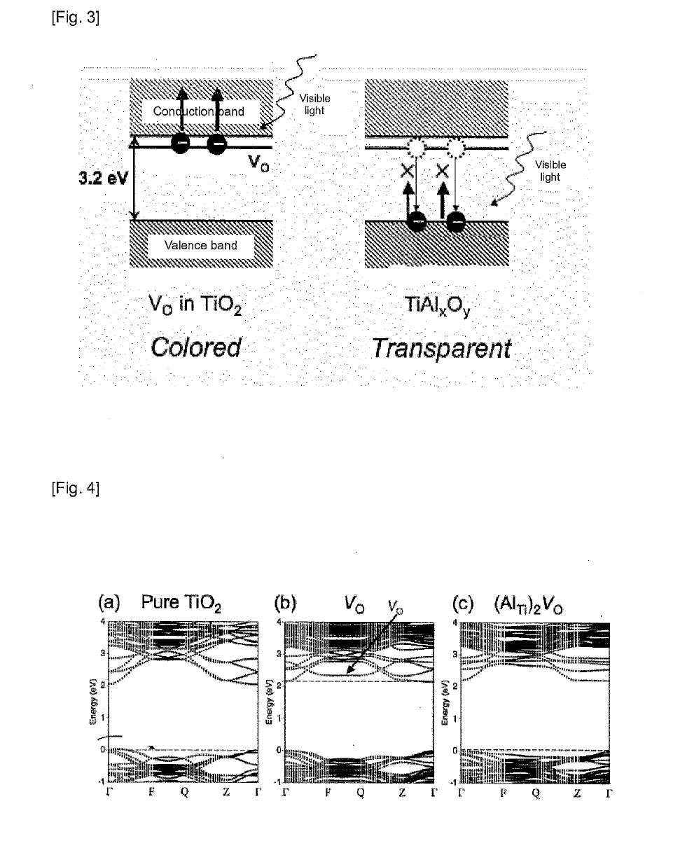

FIG. 3 is a schematic diagram showing a physical explanation for the improvement in light transmittance of Ti₁₋ₐAlₐO_{y} relative to TiO₂, due to the addition of Al₂O₃;

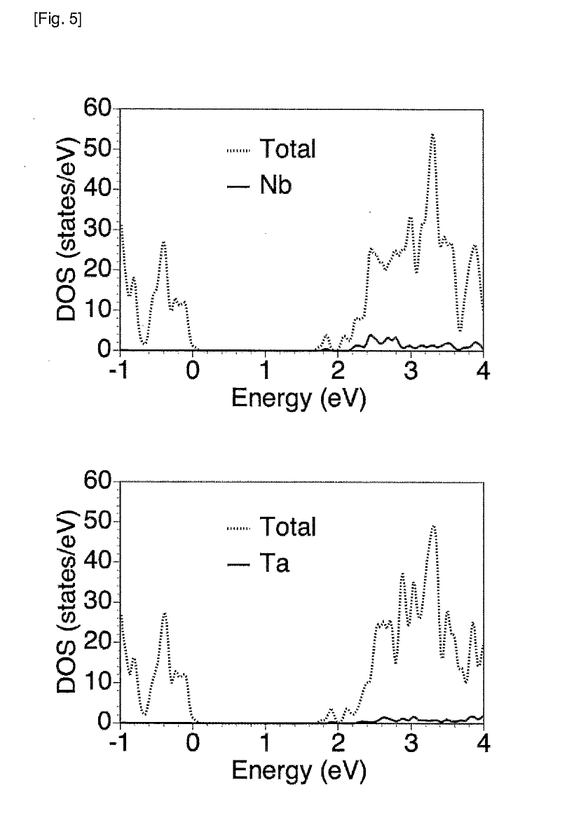

FIG. 4 is a diagram showing the energy band structure, obtained according to the first-principle calculations: (a) in the case of perfect TiO₂ crystal, (b) when an oxygen vacancy Vₒ is formed, and (c) in the case of Ti₁₋ₐAlₐO_{y}, the dotted lines in this figure representing the Fermi level;

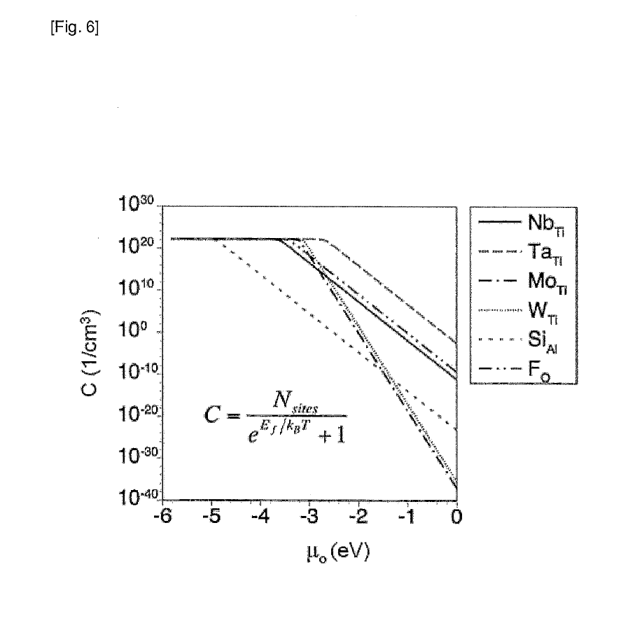

FIG. 5 is a diagram showing: (a) the density of states (DOS) when transition metal niobium Nb is added to Ti₁₋ₐAlₐO_{y}, and (b) the density of states (DOS) when transition metal tantalum Ta is added to Ti₁₋ₐAlₐO_{y}, each time obtained according to the first-principle calculations;

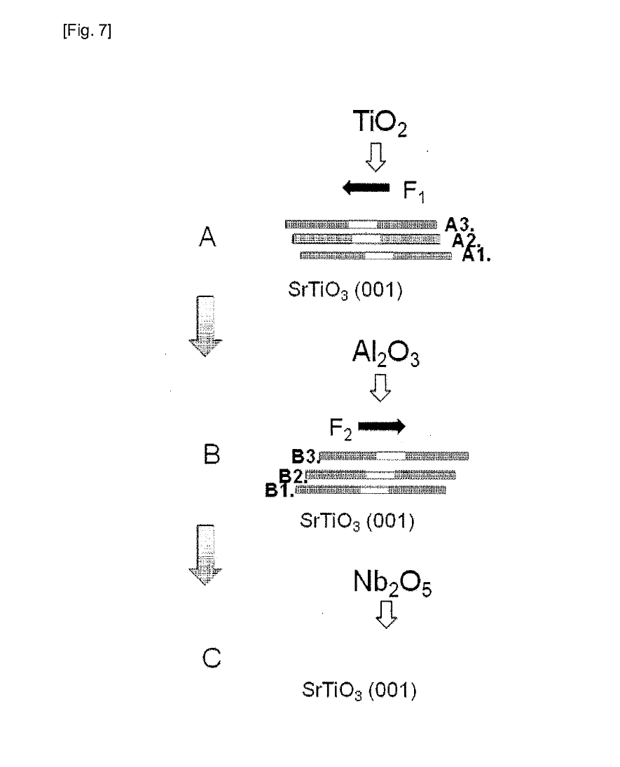

FIG. 6 is a graph showing computational results of the carrier density C after addition of various dopants to Ti₁₋ₐAlₐO_{y};

FIG. 7 is a schematic drawing showing the translational displacement of a shadow mask during a procedure for preparing a Ti₁₋ₐAlₐNb_{b}O_{y} film using a combinatorial growth process;

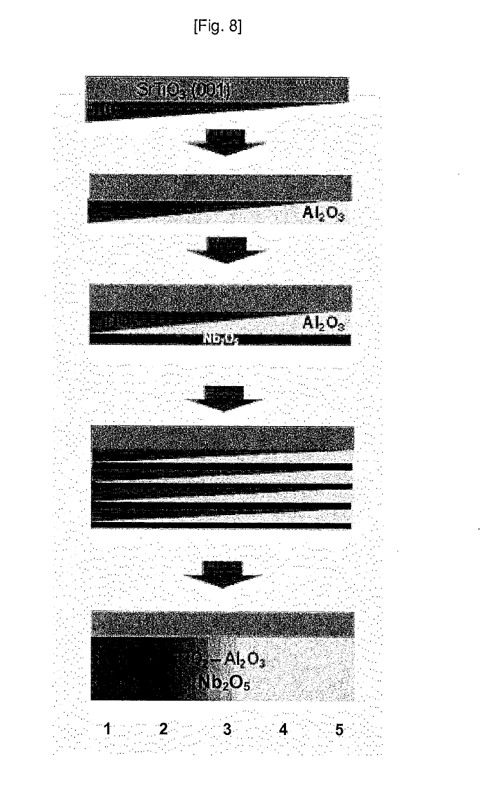

FIG. 8 is a schematic drawing showing the successive steps of the procedure for preparing a Ti_{1-a-b}AlₐNb_{b}O_{y} film using a combinatorial growth process with the moving shadow mask of FIG. 7;

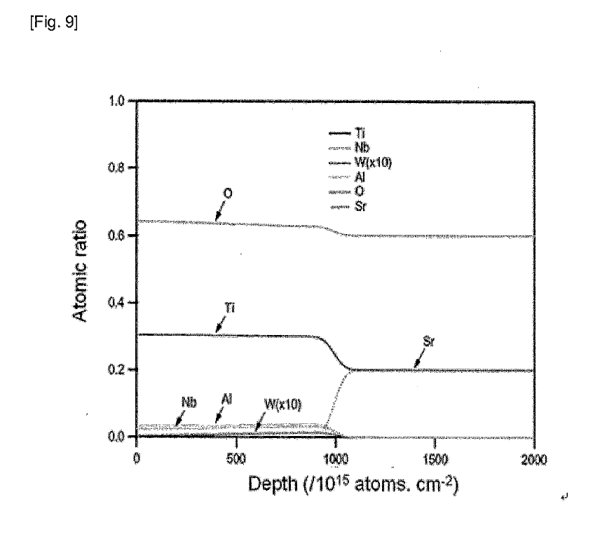

FIG. 9 is a graph showing the results of an elemental composition analysis, as determined by Rutherford backscattering spectrometry, in the depth direction of a Ti_{1-a-b}AlₐNb_{b}O_{y} film prepared using the combinatorial growth process shown in FIGS. 7 and 8;

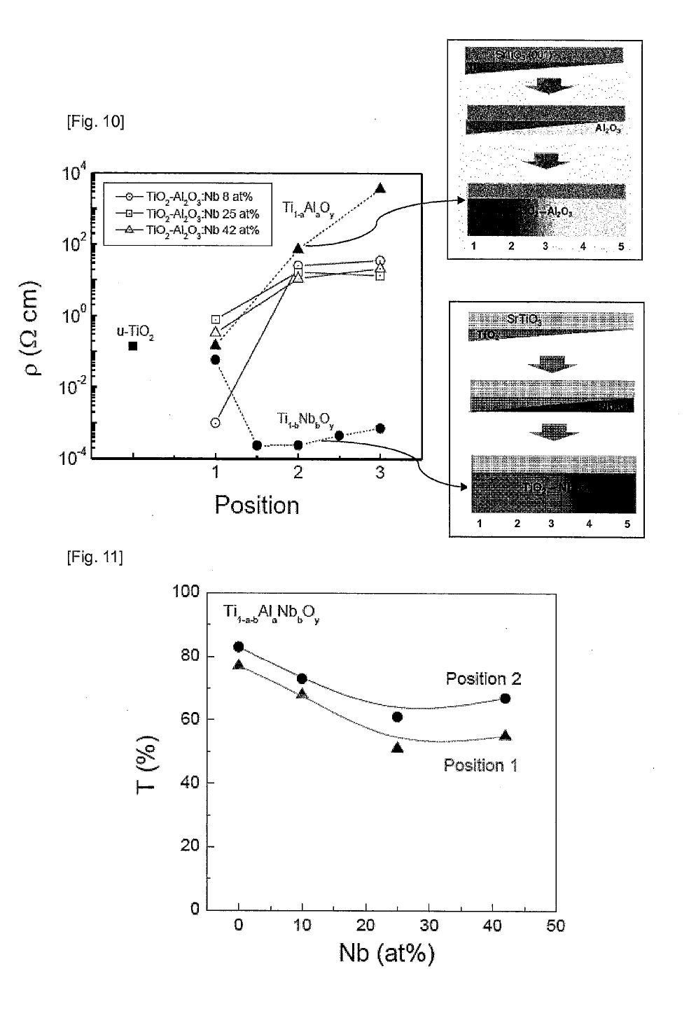

FIG. 10 is a graph showing the electrical resistivity ρ of Ti_{1-a-b}AlₐNb_{b}O_{y} films having different Nb contents prepared using the combinatorial growth process shown in FIGS. 7 and 8, as a function of the position on the surface of the film;

FIG. 11 is a graph showing the light transmittance T at 550 nm of Ti_{1-a-b}AlₐNb_{b}O_{y} films prepared using the combinatorial growth process shown in FIGS. 7 and 8, as a function of the Nb content of the film, for two positions on the surface of the film;

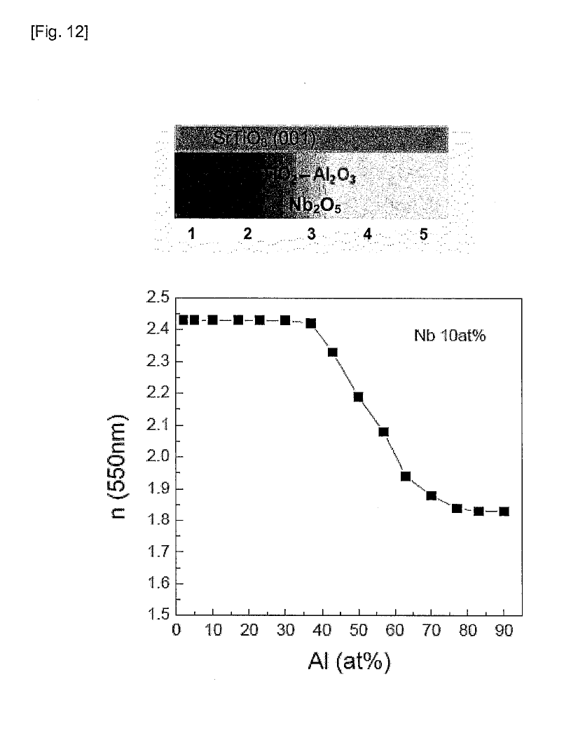

FIG. 12 is a graph showing the refractive index n at 550 nm of a Ti_{1-a-b}AlₐNb_{b}O_{y} film having a Nb content of 10 at % prepared using the combinatorial growth process shown in FIGS. 7 and 8, as a function of the Al content of the film;

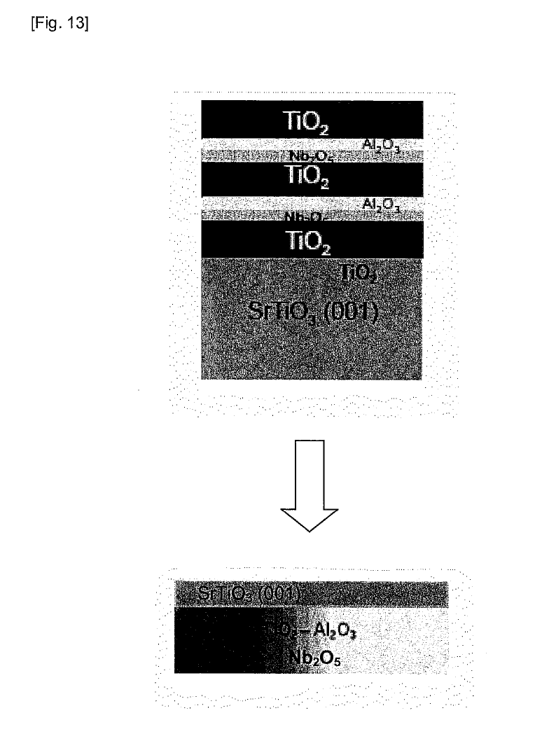

FIG. 13 is a schematic drawing showing a procedure for preparing a Ti_{1-a-b}AlₐNb_{b}O_{y} film using a layer-by-layer growth process;

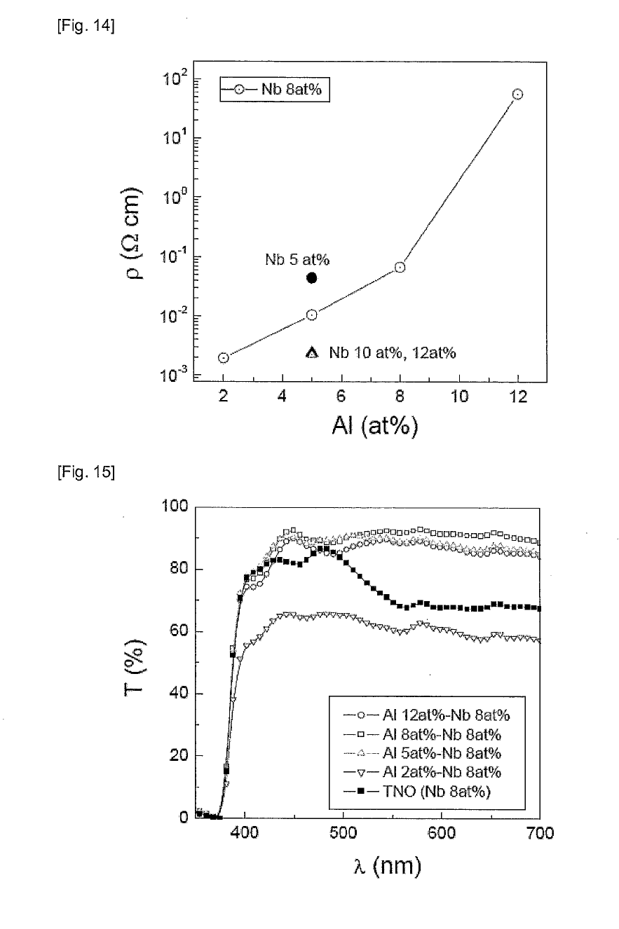

FIG. 14 is a graph showing the electrical resistivity ρ of Ti_{1-a-b}AlₐNb_{b}O_{y} films prepared using the layer-by-layer growth process shown in FIG. 13, as a function of the Al content of the film;

FIG. 15 is a graph showing the light transmittance T, over the visible light wavelength range 380 nm to 700 nm, of Ti_{1-a-b}AlₐNb_{b}O_{y} films prepared using the layer-by-layer growth process shown in FIG. 13, the Ti_{1-a-b}AlₐNb_{b}O_{y} films having a Nb content of 8 at % and different Al contents;

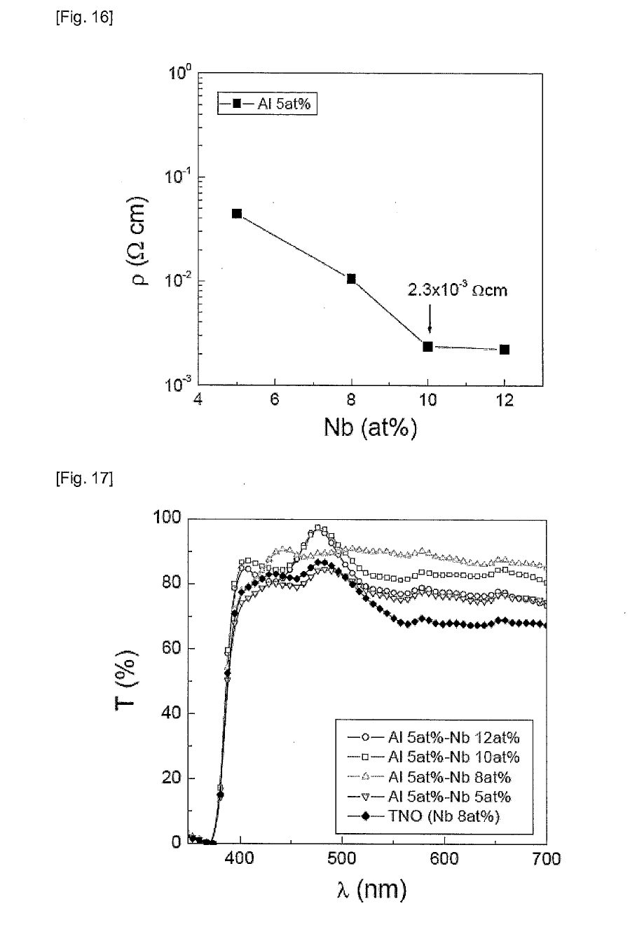

FIG. 16 is a graph showing the electrical resistivity ρ of Ti_{1-a-b}AlₐNb_{b}O_{y} films prepared using the layer-by-layer growth process shown in FIG. 13, as a function of the Nb content of the film;

FIG. 17 is a graph showing the light transmittance T, over the visible light wavelength range 380 nm to 700 nm, of Ti_{1-a-b}AlₐNb_{b}O_{y} films prepared using the layer-by-layer growth process shown in FIG. 13, the films having an Al content of 5 at % and different Nb contents;

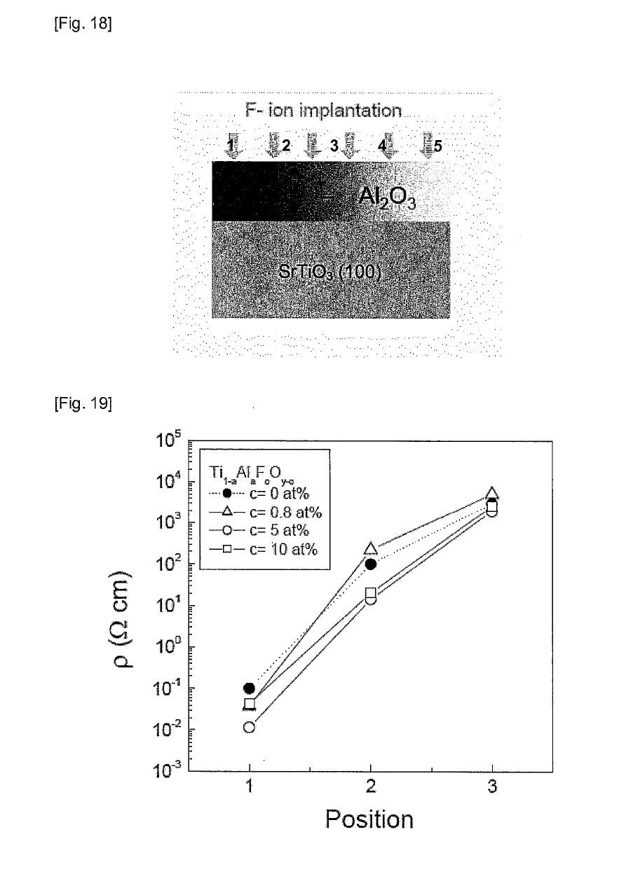

FIG. 18 is a schematic drawing showing a procedure for preparing a Ti₁₋ₐAlₐF_{c}O_{y-c} film using a combinatorial growth process of a Ti₁₋ₐAlₐO_{y} film followed by fluorine ion implantation in the Ti₁₋ₐAlₐO_{y} film;

FIG. 19 is a graph showing the electrical resistivity ρ of Ti₁₋ₐAlₐF_{c}O_{y-c} films having different fluorine contents prepared using the process shown in FIG. 18, as a function of the position on the surface of the film;

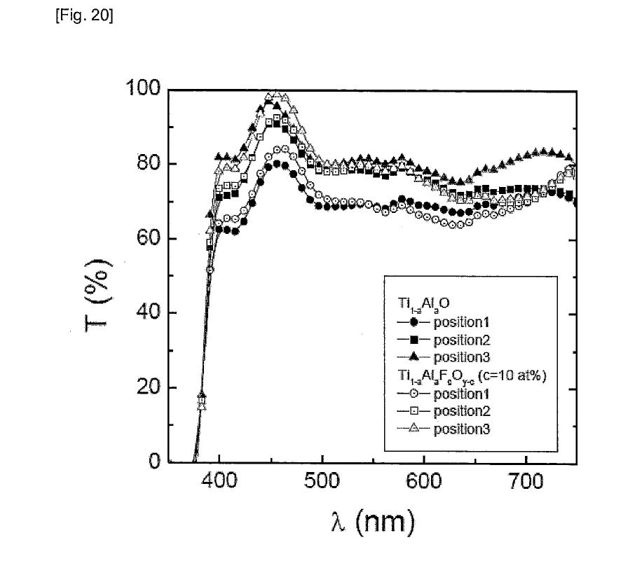

FIG. 20 is a graph showing the light transmittance T, over the visible light wavelength range 380 nm to 780 nm, of Ti₁₋ₐAlₐF_{c}O_{y-c} films having a fluorine content of 10 at % prepared using the process shown in FIG. 18, for three positions on the surface of the film.

Hereinafter, the present invention is described in detail.

The present invention provides a transparent conductor material (or TCO) in the form of a film, which comprises as its main component titanium oxide doped with aluminum Ti₁₋ₐAlₐO_{y} and at least one other dopant added to Ti₁₋ₐAlₐO_{y}, the dopant being:
either a transition metal X, in particular Nb, Ta, W or Mo, where the transition metal X substitutes Ti in the form Ti_{1-a-b}AlₐX_{b}O_{y};
or fluorine F, where F substitutes O in the form Ti₁₋ₐAlₐF_{c}O_{y-c}.

More precisely, according to the present invention, a film-shaped transparent semiconductor material is formed which has improved properties compared to known semiconductor materials. The inventors have discovered that doping titanium oxide both with aluminum and at least one other dopant as described above makes it possible to obtain a film-shaped transparent semiconductor material that has a high and flat visible light transmittance, in particular a visible light transmittance higher and flatter than that of semiconductor materials made of titanium oxide doped with niobium or tantalum, and a low electrical resistivity comparable to that of semiconductor materials made of titanium oxide doped with niobium or tantalum.

The inventors have shown both theoretically and experimentally the advantages obtained with the invention. The theoretical approach is firstly explained in detail below.

FIG. 1 shows the energy band structure of TiAlO_{3.5}, corresponding to a TiO₂:Al₂O₃ ratio of 50:50, as determined by the first-principle calculations.

FIG. 1 shows that the optical band gap of TiAlO_{3.5} does not change as compared to that of TiO₂, which confirms that TiAlO_{3.5} is a semiconductor material. In this respect, it can be noted that the calculated optical band gap is about 2.0 eV, as compared with the actual optical band gap of TiO₂ which is 3.2 eV. Such a difference between calculated and experimental values is a common problem in this type of calculation. Yet, the absolute values of the calculation results are not important. What is important is the fact that there is no difference between the band gaps of TiO₂ and TiAlO_{3.5}.

In the model of TiAlO_{3.5} used for the first-principle calculations, a 12-atom cell was prepared by combining two 6-atom unit cells of TiO₂ anatase phase, with two of the Ti sites being replaced by Al atoms as shown in FIG. 2. In addition, one oxygen atom was eliminated for stoichiometric reasons. The first-principle calculations were performed by imposing a periodic boundary condition on the model.

FIG. 3 is a schematic diagram showing the physical mechanism by which addition of Al to TiO₂ improves light transmittance. It is considered that addition of Al inactivates the oxygen vacancies in TiO₂, and that the resulting disappearance, in the gap, of the energy level of the oxygen vacancies suppresses visible light absorption, which in turn improves light transmittance. The disappearance of the energy level of the oxygen vacancies caused by the substitution of Ti atoms by Al atoms was confirmed by the first-principle calculations, as shown in FIG. 4.

FIG. 4(a) shows the energy band structure for perfect TiO₂ crystal. In this case, the Fermi level is located at the top of the valence band, so that the energy band structure of the crystal does not allow visible light absorption.

As shown in FIG. 4(b), the oxygen vacancy Vₒ causes the Fermi level to be located at the bottom end of the conduction band, which in turn causes the crystal to absorb visible light and to become colored, resulting in lower light transmittance.

The inventors consider that the substitution of the two Ti atoms by Al atoms in the region close to the oxygen vacancy pulls the Fermi level back to the top of the valence band, as shown in FIG. 4(c), which suppresses visible light absorption, resulting in an improvement in the light transmittance.

Nb and Ta are dopants for titanium oxide that make it possible to obtain TCO materials having a relatively low electrical resistivity. In the examples shown in FIG. 5, Nb and Ta are considered as representative of other transition metal elements or other elements that make it possible to decrease the electrical resistivity.

FIG. 5(a) shows the density of states when transition metal Nb is added to TiAlO_{3.5}, whereas FIG. 5(b) shows the density of states when transition metal Ta is added to TiAlO_{3.5}. Both results were obtained using first-principle calculations. These results show that TiAlO_{3.5} in which Ta has been added has substantially the same electronic structure as TiAlO_{3.5} in which Nb has been added. Thus, even if the embodiments described below involve doping with Nb, it is considered that doping with Ta makes it possible to obtain similar effects to those obtained with Nb.

FIG. 6 shows computational results of the carrier density C obtained by addition of various dopants in TiAlO_{3.5}. In FIG. 6, μₒ is the oxygen chemical potential. For the first-principle calculations, density-functional theory (DFT) within the local-density approximation (LDA) was used, using the projector augmented wave pseudopotentials. A 44-atom supercell of TiAlO_{3.5} was used to estimate the formation energy E_{f} of each substitutional impurity at each lattice site. The carrier density C is determined at room temperature and defined by the expression:

$$C = \frac{{N}_{sites}}{{e}^{{E}_{f} / {k}_{B} T} + 1} ,$$

where Nₛᵢₜₑₛ is the number of available sites for dopants per supercell, k_{B} is the Boltzmann constant and T is the temperature.

FIG. 6 shows that doping Ti₁₋ₐAlₐO_{y} with Nb, Ta, Mo or W, which substitute Ti, or with F, which substitutes O, results in an increase in the carrier density, and thus in the conductivity. In this figure, it can be seen that the addition of Si, which substitutes Al, can also improve the conductivity. In particular, this shows that doping Ti_{1-a-b}AlₐX_{b}O_{y} or Ti₁₋ₐAlₐF_{c}O_{y-c} with Si can further improve the conductivity, where Ti_{1-a-b}AlₐX_{b}O_{y} is Ti₁₋ₐAlₐO_{y} doped with a transition metal such as Nb, Ta, Mo or W, and Ti₁₋ₐAlₐF_{c}O_{y-c} is Ti₁₋ₐAlₐO_{y} doped with fluorine. Other dopants substituting Al, such as Ge or Sn, can also be used instead of or in combination with Si in order to improve the conductivity of Ti_{1-a-b}AlₐX_{b}O_{y} or Ti₁₋ₐAlₐF_{c}O_{y-c}.

Hereinafter, the invention is described in detail with reference to experimental examples. These examples are presented only for the purpose of better understanding of the invention, it being understood that the invention is not limited to these examples.

In a first series of experiments described below with reference to FIGS. 7 to 16, the properties of titanium oxide doped both with aluminum and niobium are investigated.

FIGS. 7 and 8 show the procedure for preparing a Ti_{1-a-b}AlₐNb_{b}O_{y} film using a combinatorial growth process with a moving shadow mask. A multilayer film having a total thickness of 70 nm, comprising successive layers of TiO₂, Al₂O₃, Nb₂O₅, is deposited by the pulsed laser deposition (PLD) technique onto a strontium titanate SrTiO₃ (001) substrate. At the time of deposition, the oxygen pressure is 2×10⁻³ Pa (1.5×10⁻⁵ Torr) and the temperature of the substrate is 300° C.

Sintered pellets of TiO₂, Al₂O₃ and Nb₂O₅ are used as PLD targets, respectively for the deposition of the TiO₂, Al₂O₃ and Nb₂O₅ layers. At the time of deposition, the distance between each target and the substrate is 50 mm, and the substrate is not rotated. The laser pulses are supplied by a KrF excimer laser source (λ=248 nm) with an energy of 150 mJ/m² during irradiation and a frequency of 3 Hz.

The shadow mask visible in FIG. 7 includes a rectangular opening intended for the successive deposition of the TiO₂ and Al₂O₃ layers. The mask is moved from right to left during the deposition of each TiO₂ layer, as shown by arrow F₁ of FIG. 7 and successive positions A1, A2, A3 of the mask, and is moved from left to right during the deposition of each Al₂O₃ layer, as shown by arrow F₂ of FIG. 7 and successive positions B1, B2, B3 of the mask. No mask is used during the deposition of each Nb₂O₅ layer. In this way, a Ti_{1-a-b}AlₐNb_{b}O_{y} film is obtained, which has a gradient composition of TiO₂ and Al₂O₃, and a uniform composition of Nb₂O₅.

Though it appears in FIG. 8 as if the composition gradient was obtained by a gradient in the thickness of the TiO₂ and Al₂O₃ layers, this representation was used only for the convenience of the drawing. In fact, the composition gradient is obtained by a gradient in the distribution density of TiO₂ and Al₂O₃ in the individual layers, the thicknesses of these layers being uniform over the surface of the substrate. More specifically, the distribution density of TiO₂ decreases from left to right in FIG. 8, whereas the distribution density of Al₂O₃ increases from left to right. An elemental composition analysis of the Ti_{1-a-b}AlₐNb_{b}O_{y} film in the depth direction, as determined by Rutherford backscattering spectrometry, confirms that the elements Ti, Al, Nb and O are distributed uniformly in the film, as shown in FIG. 9.

FIG. 8 defines successive positions 1, 2, 3, 4, 5 from left to right on the surface of the Ti_{1-a-b}AlₐNb_{b}O_{y} film. The successive positions 1 to 5 on the film correspond to an increasing Al content of the film. In particular, position 1 corresponds to an Al content a of 10 at %, position 2 corresponds to an Al content a of 15 at %, and position 3 corresponds to an Al content a of 50 at %.

FIG. 10 shows the electrical resistivity ρ, between positions 1 and 3, of three Ti_{1-a-b}AlₐNb_{b}O_{y} films prepared using the combinatorial growth process described above, with different Nb contents b of 8 at %, 25 at % and 42 at %, respectively.

As comparison examples, the electrical resistivity ρ of a film of titanium oxide doped with aluminum only (Ti₁₋ₐAlₐO_{y}) and the electrical resistivity ρ of titanium oxide doped with niobium only (Ti_{1-b}Nb_{b}O_{y}) are also shown in FIG. 10. Each film of Ti₁₋ₐAlₐO_{y} and Ti_{1-b}Nb_{b}O_{y} is prepared using a combinatorial growth process with a moving mask analogous to the process used for preparing the Ti_{1-a-b}AlₐNb_{b}O_{y} films, as shown schematically on the right of FIG. 10. As it can be seen on the right of FIG. 10, the successive positions 1 to 3 on the Ti₁₋ₐAlₐO_{y} film correspond to increasing Al contents, in particular position 1 corresponds to an Al content of 10 at %, position 2 corresponds to an Al content of 15 at %, and position 3 corresponds to an Al content of 50 at %. In the same way, the successive positions 1 to 3 on the Ti_{1-b}Nb_{b}O_{y} film correspond to increasing Nb contents, in particular position 1 corresponds to a Nb content of 4 at %, position 2 corresponds to a Nb content of 12 at %, and position 3 corresponds to a Nb content of 50 at %.

FIG. 10 shows that, for the three Ti_{1-a-b}AlₐNb_{b}O_{y} films, the electrical resistivity ρ increases when the Al content of the film increases. The results are shown for Al contents between positions 1 and 3 only, it being understood that higher Al contents beyond position 3 correspond to even higher resistivity values. It can be seen in FIG. 10 that for positions 1 to 3, which correspond to an Al content a of the film between 10 at % and 50 at %, the electrical resistivity ρ of the three Ti_{1-a-b}AlₐNb_{b}O_{y} films is either of the same order of magnitude as the electrical resistivity ρ of the Ti₁₋ₐAlₐO_{y} film, around position 1 for the films having Nb contents b of 25 at % and 42 at %, or lower than the electrical resistivity ρ of the Ti₁₋ₐAlₐO_{y} film, for all positions 1 to 3 of the film having a Nb content b of 8 at % and between positions 1 and 3 for the films having a Nb content b of 25 at % and 42 at %.

It can be noted in FIG. 10 that the Ti_{1-a-b}AlₐNb_{b}O_{y} film having a Nb content b of 8 at % exhibits a remarkably low electrical resistivity ρ between positions 1 and 2, which correspond to an Al content of the film of less than 15 at %. In particular, at position 1, the electrical resistivity ρ of the Ti_{1-a-b}AlₐNb_{b}O_{y} film having a Nb content b of 8 at % is of the order of 10⁻³ Ωcm, which is comparable to the electrical resistivity ρ of the Ti_{1-b}Nb_{b}O_{y} film having a Nb content b between 8 and 50 at %. Thus, as regards lowering the electrical resistivity, a composition of a Ti_{1-a-b}AlₐNb_{b}O_{y} film such that the Nb content b is of the order of 8 at % and the Al content a is below 15 at % seems to be particularly efficient.

The evolution of the light transmittance T at 550 nm as a function of the Nb content b of the Ti_{1-a-b}AlₐNb_{b}O_{y} film prepared using the combinatorial growth process described above, respectively at position 1 and at position 2, has also been evaluated. The results, which are shown in FIG. 11, show that the Nb content b should preferably be kept below 15 at % in order to have a light transmittance T of at least 70%.

FIG. 12 shows the refractive index n at 550 nm of a Ti_{1-a-b}AlₐNb_{b}O_{y} film prepared using the combinatorial growth process described above with a Nb content b of 10 at %, as a function of the Al content a of the film. FIG. 12 shows that the refractive index n at 550 nm is high, of the order of 2.4, when the Al content a of the film is below 30 at %. Thus, as regards obtaining a relatively high refractive index of the film, the Al content a should preferably be kept below 30 at %.

In order to narrow the ranges of Al content a and Nb content b of a Ti_{1-a-b}AlₐNb_{b}O_{y} film making it possible to reach optimum values of both the electrical resistivity ρ and the light transmittance T of the film, additional series of Ti_{1-a-b}AlₐNb_{b}O_{y} films were prepared using a layer-by-layer growth process, with specific Al contents of 2 at %, 5 at %, 8 at %, 10 at %, 12 at %, and specific Nb contents of 5 at %, 8 at %, 10 at % and 12 at %.

FIG. 13 shows the procedure for preparing a Ti_{1-a-b}AlₐNb_{b}O_{y} film using the layer-by-layer growth process. A layer-by-layer structure having a total thickness of 100 nm, comprising successive layers of TiO₂, Al₂O₃, Nb₂O₅, is deposited by the pulsed laser deposition (PLD) technique onto a strontium titanate SrTiO₃ (001) substrate with an oxygen pressure of 2×10⁻³ Pa (1.5×10⁻⁵ Torr). The temperature of the substrate at the time of deposition is 300° C.

Sintered pellets of TiO₂, Al₂O₃ and Nb₂O₅ are used as PLD targets, respectively for the deposition of the TiO₂, Al₂O₃ and Nb₂O₅ layers. At the time of deposition, the distance between each target and the substrate is 50 mm, and the substrate is not rotated. The laser pulses are supplied by a KrF excimer laser source (λ=248 nm) with an energy of 150 mJ/m² during irradiation and a frequency of 3 Hz. The Al and Nb contents of the Ti_{1-a-b}AlₐNb_{b}O_{y} film can easily be adjusted according to the relative thicknesses of the successive TiO₂, Al₂O₃ and Nb₂O₅ layers.

FIG. 14 shows the electrical resistivity ρ as a function of the Al content a in at %, for Ti_{1-a-b}AlₐNb_{b}O_{y} films prepared using the layer-by-layer growth process described above, where each of the Ti_{1-a-b}AlₐNb_{b}O_{y} films has a Nb content b of 8 at %. This figure shows a rapid increase in the electrical resistivity ρ when the Al content a exceeds 8 at %. An Al content a of 2 at % corresponds to the lowest value of the electrical resistivity ρ, equal to 1.9×10⁻³ Ωcm.

FIG. 15 shows the light transmittance T over the visible light wavelength range for Ti_{1-a-b}AlₐNb_{b}O_{y} films prepared using the layer-by-layer growth process described above, where each of the Ti_{1-a-b}AlₐNb_{b}O_{y} films has a Nb content b of 8 at % and the Ti_{1-a-b}AlₐNb_{b}O_{y} films differ from one another in their Al content a.

It can be seen in FIG. 15 that the Ti_{1-a-b}AlₐNb_{b}O_{y} film having the lowest Al content a, equal to 2 at %, has the lowest light transmittance T over the visible light wavelength range. All other Al contents a, equal to 5 at %, 8 at % and 12 at %, respectively, make it possible to reach values of the light transmittance T over the visible light wavelength range that are higher than the light transmittance T of titanium oxide doped with niobium only (Ti_{1-b}Nb_{b}O_{y}), having a corresponding Nb content of 8 at %. As shown in FIG. 15, the values of the light transmittance T over the wavelength range 400 nm to 700 nm of the three Ti_{1-a-b}AlₐNb_{b}O_{y} films having Al contents a of 5 at %, 8 at % and 12 at % are higher than 80%.

In view of the above results, an adjusted value of the Al content a in Ti_{1-a-b}AlₐNb_{b}O_{y} films having a Nb content b is 8 at %, making it possible to reach optimum values of both the electrical resistivity ρ and the light transmittance T over the visible light wavelength range, is around 5 at %.

FIG. 16 shows the electrical resistivity ρ as a function of the Nb content b in at %, for Ti_{1-a-b}AlₐNb_{b}O_{y} films prepared using the layer-by-layer growth process described above, where each of the Ti_{1-a-b}AlₐNb_{b}O_{y} films has an Al content a of 5 at %. This figure shows that the electrical resistivity ρ is particularly low when the Nb content b exceeds 10 at %, which corresponds to a value of the electrical resistivity ρ equal to 2.3×10⁻³ Ωcm.

FIG. 17 shows the light transmittance T over the visible light wavelength range for Ti_{1-a-b}AlₐNb_{b}O_{y} films prepared using the layer-by-layer growth process described above, where each of the Ti_{1-a-b}AlₐNb_{b}O_{y} films has an Al content a of 5 at % and the Ti_{1-a-b}AlₐNb_{b}O_{y} films differ from one another in their Nb content b. It can be seen in FIG. 17 that the light transmittance T over the wavelength range 400 nm to 700 nm of the Ti_{1-a-b}AlₐNb_{b}O_{y} films is higher than 80%.

Thus, it appears from FIGS. 14 to 17 that Ti_{1-a-b}AlₐNb_{b}O_{y} films having an Al content a between 2 at % and 12 at %, preferably between 4 at % and 8 at %, and a Nb content b between 3 at % and 12 at %, preferably between 5 at % and 12 at %, exhibit a high light transmittance T over the visible light wavelength range, even higher than that of films of titanium oxide doped with niobium (Ti_{1-b}Nb_{b}O_{y}), and a low electrical resistivity ρ, comparable to that of films of titanium oxide doped with niobium (Ti_{1-b}Nb_{b}O_{y}).

In addition, it can be seen in FIG. 15 that the light transmittance T over the wavelength range 400 nm to 700 nm of the three Ti_{1-a-b}AlₐNb_{b}O_{y} films having Al contents a of 5 at %, 8 at % and 12 at %, is flatter than that of films of titanium oxide doped with niobium only (Ti_{1-b}Nb_{b}O_{y}). This substantially flat light transmittance of Ti_{1-a-b}AlₐNb_{b}O_{y} over the wavelength range 400 nm to 700 nm is particularly advantageous in application areas where color changes are undesirable. Indeed, when the light transmittance is not uniform over the visible light wavelength range, color tone compensating filters are needed for some applications, causing increased production costs, as well as additional light absorption.

In order to quantitatively estimate the flatness of the light transmittance T over the wavelength range 400 nm to 700 nm, a flatness index r is introduced, which is determined as described below.

First, the regression line y=ax+b of the set of points {λⱼ, Ln(Tⱼ)}_{0≦j≦n} is obtained, by means of least mean square approximation, where (λⱼ)_{0≦j≦n} are wavelength values within the wavelength range 400 nm to 700 nm, and (Tⱼ)_{0≦j≦n}, are the light transmittance values of the Ti_{1-a-b}AlₐNb_{b}O_{y} film measured at each of the wavelengths (═ⱼ)_{0≦j≦n}. Then, the light transmittance flatness index r is determined as the ratio

$$r = \frac{{y}_{λ = 400 nm}}{{y}_{λ = 700 nm}} .$$

The values of the flatness index r of the Ti_{1-a-b}AlₐNb_{b}O_{y} films having a Nb content b of 8 at %, and respective Al contents a of 5 at %, 8 at % and 12 at %, are 0.99947270, 0.98567034 and 0.99177712. In comparison, the value of the flatness index r of the film of titanium oxide doped with niobium only (Ti_{1-b}Nb_{b}O_{y}) having a Nb content b of 8 at % is 1.05985682. In the example of FIG. 15, the flatness index r is within the range 1±0.066. Through optimization of the composition of Ti_{1-a-b}AlₐNb_{b}O_{y}, the flatness index r of the transparent electric conductor according to the invention can be within the range 1±0.05, preferably 1±0.04.

In the calculation of the flatness index values above, more than seven hundred data points have been used, corresponding to different wavelength values within the wavelength range 400 nm to 700 nm. A data set corresponding to a different number of data points may of course be used for the calculation. It can be observed that the flat light transmittance over the wavelength range 400 nm to 700 nm of Ti_{1-a-b}AlₐNb_{b}O_{y} having a Nb content b of 8 at %, is maintained over a wide range of Al contents a.

In a second series of experiments described below with reference to FIGS. 18 to 20, the properties of titanium oxide doped both with aluminum and fluorine are investigated.

FIG. 18 shows the procedure for preparing a Ti₁₋ₐAlₐF_{c}O_{y-c} film in which, in a first step, a combinatorial growth process with a moving shadow mask is used to form a Ti₁₋ₐAlₐO_{y} film and, in a second step, fluorine ion implantation is performed in the Ti₁₋ₐAlₐO_{y} film in order to form the Ti₁₋ₐAlₐF_{c}O_{y-c} film. Ti₁₋ₐAlₐO_{y} doped with fluorine is referred to as Ti₁₋ₐAlₐF_{c}O_{y-c}, since F replaces some of the O, as opposed to Ti₁₋ₐAlₐO_{y} doped with niobium in which Nb replaces some of the Ti.

In a first step of the procedure shown in FIG. 18, a film having a total thickness of 100 nm and comprising successive layers of TiO₂ and Al₂O₃ is deposited by the pulsed laser deposition (PLD) technique onto a strontium titanate SrTiO₃ (100) substrate. At the time of deposition, the oxygen pressure is 2×10⁻³ Pa (1.5×10⁻⁵ Torr) and the temperature of the substrate is 300° C. A shadow mask similar to the one shown in FIG. 7 is moved from right to left during the deposition of each TiO₂ layer, and moved from left to right during the deposition of each Al₂O₃ layer. In this way, a Ti₁₋ₐAlₐO_{y} film is obtained, which has a gradient composition of TiO₂ and Al₂O₃.

Sintered pellets of TiO₂ and Al₂O₃ are used as PLD targets, respectively for the deposition of the TiO₂ and Al₂O₃ layers. At the time of deposition, the distance between each target and the substrate is 50 mm, and the substrate is not rotated. The laser pulses are supplied by a KrF excimer laser source (λ=248 nm) with an energy of 150 mJ/m² during irradiation and a frequency of 3 Hz.

In a second step of the procedure shown in FIG. 18, fluorine ions are implanted into the Ti₁₋ₐAlₐO_{y} film. It is noted that Ti₁₋ₐAlₐO_{y} may also be doped with fluorine by other methods than ion implantation, for example by pulsed laser deposition (PLD) with a fluoride target, so that fluorine layers are inserted between successive TiO₂ and Al₂O₃ layers, in a way similar to the Nb₂O₅ layers in FIG. 8. Ion implantation is used here only for experimental convenience.

The obtained Ti₁₋ₐAlₐF_{c}O_{y-c} film has a gradient composition of TiO₂ and Al₂O₃, and a uniform composition of fluorine. FIG. 18 defines successive positions 1, 2, 3, 4, 5, from left to right on the surface of the Ti₁₋ₐAlₐF_{c}O_{y-c} film. The successive positions 1 to 5 on the film correspond to increasing Al contents of the film. In particular, position 1 corresponds to an Al content a of 10 at %, position 2 corresponds to an Al content a of 25 at %, and position 3 corresponds to an Al content a of 50 at %.

FIG. 19 shows the electrical resistivity ρ, between positions 1 and 3, of three Ti₁₋ₐAlₐF_{c}O_{y-c} films prepared using the procedure described above with different F contents c of, respectively: 0.8 at %, corresponding to a fluorine ion implantation concentration of 10¹⁵/cm²; 5 at %, corresponding to a fluorine ion implantation concentration of 10¹⁶/cm²; and 10 at %, corresponding to a fluorine ion implantation concentration of 10¹⁷/cm².

As a comparison example, the electrical resistivity ρ of a film of titanium oxide doped with aluminum only (Ti₁₋ₐAlₐO_{y}, corresponding to c=0 at %) is also shown in FIG. 19. The Ti₁₋ₐAlₐO_{y} film is prepared using only the first step of the procedure described above, that is to say only the combinatorial growth process with a moving mask, without the subsequent fluorine ion implantation. The successive positions 1 to 3 on the Ti₁₋ₐAlₐO_{y} film correspond to increasing Al contents.

It can be seen in FIG. 19 that the three Ti₁₋ₐAlₐF_{c}O_{y-c} films exhibit a lower electrical resistivity ρ than the resistivity of the Ti₁₋ₐAlₐO_{y} film. The results are shown for Al contents a between positions 1 and 3 only, it being understood that higher Al contents a beyond position 3 correspond to even higher electrical resistivity values. FIG. 19 also shows that, at position 1, a fluorine content c of 5 at % results in the lowest value of the electrical resistivity ρ, equal to 9×10⁻³ Ωcm, as compared to the two other fluorine contents c of 0.8 at % and 10 at %.

FIG. 20 shows the light transmittance T over the visible light wavelength range of Ti₁₋ₐAlₐF_{c}O_{y-c} films prepared using the procedure described above, for positions 1 to 3 on the films, where each of the Ti₁₋ₐAlₐF_{c}O_{y-c} films has a fluorine content c of 10 at %. As a comparison example, the light transmittance T over the visible light wavelength range of a film of titanium oxide doped with aluminum only (Ti₁₋ₐAlₐO_{y}) is also shown in FIG. 20.

By a comparison between the curves of FIG. 20 corresponding to positions 1, 2, 3, it can be seen that the light transmittance T increases when the Al content of the film increases. FIG. 20 also shows that, at each position 1, 2, 3 on the film, the addition of fluorine makes it possible to maintain high values of the light transmittance T over the visible light wavelength range, that are substantially the same as the values of the light transmittance T of titanium oxide doped with aluminum only (Ti₁₋ₐAlₐO_{y}). As shown in FIG. 20, the T values over the wavelength range 400 nm to 700 nm at positions 2 and 3 on the Ti₁₋ₐAlₐF_{c}O_{y-c} film are higher than 70%.

In addition, it can be seen in FIG. 20 that the light transmittance T over the wavelength range 400 nm to 700 nm of the Ti₁₋ₐAlₐF_{c}O_{y-c} film is substantially flat at each position 1, 2, 3, which is particularly advantageous in application areas where color changes are undesirable. The values of the flatness index r of the Ti₁₋ₐAlₐF_{c}O_{y-c} films having a F content c of 10 at % and respective Al contents a of 0.8 at % (position 1), 5 at % (position 2) and 10 at % (position 3), are 1.03352, 1.04656 and 1.06540.

These data show that doping Ti₁₋ₐAlₐO_{y} with fluorine causes little effect on the flatness index r, as compared to doping TiO₂ with niobium (Ti_{1-b}Nb_{b}O_{y}) as explained before with reference to FIG. 15. In the example of FIG. 20, the flatness index r of Ti₁₋ₐAlₐF_{c}O_{y-c} is within the range 1±0.066. Through optimization of the composition of Ti₁₋ₐAlₐF_{c}O_{y-c}, the flatness index r of the transparent electric conductor according to the invention can be within the range 1±0.05, preferably 1±0.04.

Thus, it appears that Ti₁₋ₐAlₐF_{c}O_{y-c} films having an Al content a lower than 50 at % and a F content c lower than 10 at % exhibit, on the one hand, a high light transmittance T over the visible light wavelength range and a low electrical resistivity ρ, both of which are comparable to those of films of titanium oxide doped with niobium (Ti_{1-b}Nb_{b}O_{y}), and, on the other hand, a flatter light transmittance T over the visible light range than that of films of titanium oxide doped with niobium (Ti_{1-a-b}Nb_{b}O_{y}).

The effects of annealing Ti₁₋ₐAlₐF_{c}O_{y-c} films on the electrical resistivity ρ and the light transmittance T have also been evaluated, as shown in Tables 1 and 2 below. The Ti₁₋ₐAlₐF_{c}O_{y-c} films having different fluorine contents c have been annealed in H₂/N₂ mixed gas atmosphere at 650° C. for about one hour.

The electrical resistivity ρ at position 1 on each Ti₁₋ₐAlₐF_{c}O_{y-c} film has been measured, before and after annealing. The results are given in Table 1 below:

TABLE 1

| | ρ (Ωcm) | | |
|---|---|---|---|
| Ti₁₋ₐAlₐF_{c}O_{y-c} (pos 1) | 10¹⁵/cm² | 10¹⁶/cm² | 10¹⁷/cm² |
| Before annealing | 4 × 10⁻² | 9 × 10⁻³ | 4.3 × 10⁻² |
| After annealing | 10⁻³ | 7 × 10⁻⁴ | 2 × 10⁻³ |

The results of Table 1 show that, for each of the tested Ti₁₋ₐAlₐF_{c}O_{y-c} films, the electrical resistivity ρ of the film after annealing is decreased by more than one order of magnitude relative to the electrical resistivity ρ of the film prior to annealing.

The light transmittance T at position 1 on each Ti₁₋ₐAlₐF_{b}O_{y-c} film has also been measured, before and after annealing. The results are given in Table 2 below:

TABLE 2

| | T (%) | | | | | |
|---|---|---|---|---|---|---|
| | Ti₁₋ₐAlₐF_{c}O_{y-c} (pos 1) | | | | | |
| | 10¹⁵/cm² | | 10¹⁶/cm² | | 10¹⁷/cm² | |
| | λ | | | | | |
| | 450 nm | 550 nm | 450 nm | 550 nm | 450 nm | 550 nm |
| Before annealing | 81 | 66 | 80 | 63 | 85 | 67 |
| After annealing | — | — | 87 | 68 | 79 | 63 |

The results of Table 2 show that, for the tested Ti₁₋ₐAlₐF_{c}O_{y-c} films, the light transmittance T slightly decreases after annealing.

Thus, it appears that it is possible to adjust the annealing conditions so as to conform to the requirements of a specific application of the transparent conductive film, in terms of electrical resistivity and light transmittance of the film.

On annealing, the processing time is not a critical parameter. The hydrogen content of the reducing atmosphere and the annealing temperature are more important parameters. The preferred annealing temperature range usually is 350-700° C., because annealing the transparent electric conductor of the invention above this temperature range tends to cause a phase transition to the rutile phase, whereas it is preferable to obtain the transparent electric conductor of the invention in the anatase phase which exhibits higher electron mobility, wider energy band gap, and thus lower resistivity compared to that of the rutile phase. Furthermore, when the transparent electric conductor is prepared on a glass substrate or the like, such a substrate may be damaged above this temperature range.

The transparent electric conductor according to the invention, in the form Ti_{1-a-b}AlₐX_{b}O_{y}, where X is a transition metal, or in the form Ti₁₋ₐAlₐF_{c}O_{y-c}, is applicable to a wide range of applications. In particular, the transparent electric conductor of the invention may be used as a transparent electrode for electronic devices such as, in particular, photovoltaic devices, electrochromic devices, light-emitting devices, flat-panel displays, image sensing devices. Examples of applications include thin-film photovoltaic cells, where the absorber layer may be a thin layer based on amorphous or microcrystalline silicon, or based on cadmium telluride, or else based on a chalcopyrite compound, especially of CIS or GIGS type; die-sensitized solar cells (DSSC), also known as Grätzel cells; organic photovoltaic cells; organic light-emitting diodes (OLED); light-emitting diodes (LED); panel displays; image sensors such as CCD and CMOS image sensors. The transparent electric conductor of the invention may also be used as a film for preventing adhesion of particles due to static charge; antistatic film; infrared-reflective film; UV-reflective film. The transparent electric conductor of the invention may also be used as part of a multilayer antireflective film.

1. Transparent electric conductor, comprising titanium oxide doped with aluminum and at least one other dopant:
either in the form Ti_{1-a-b}AlₐX_{b}O_{y}, where X is a dopant or a mixture of dopants selected from the group consisting of Nb, Ta, W, Mo, V, Cr, Fe, Zr, Co, Sn, Mn, Er, Ni, Cu, Zn and Sc, a is in the range 0.01 to 0.50, and b is in the range 0.01 to 0.15;
or in the form Ti₁₋ₐAlₐF_{c}O_{y-c}, where a is in the range 0.01 to 0.50, and c is in the range 0.01 to 0.10.

2. Transparent electric conductor according to claim 1, wherein a is in the range 0.02 to 0.15.

3. Transparent electric conductor according to claim 1, wherein a is in the range 0.03 to 0.12.

4. Transparent electric conductor according to claim 1, comprising Ti_{1-a-b}AlₐX_{b}O_{y}, where X is Nb, a is in the range 0.02 to 0.12, and b is in the range 0.03 to 0.12.

5. Transparent electric conductor according to claim 1, further comprising Si or Ge or Sn as a substitutional atom of Al.

6. Transparent electric conductor according to claim 1, wherein the electrical resistivity of the transparent electric conductor is at most 10⁻² Ωcm.

7. Transparent electric conductor according to claim 1, wherein the refractive index of the transparent electric conductor is at least 2.15 at 550 nm.

8. Transparent electric conductor according to claim 1, wherein the light transmittance flatness index of the transparent electric conductor is within the range 1±0.066.

9. Transparent electric conductor according to claim 1, wherein the transparent electric conductor is in the form of a film having a thickness of at most 1 micrometer.

10. Transparent electric conductor according to claim 1, wherein the light transmittance, in the wavelength range 400 nm to 700 nm, of the transparent electric conductor in the form of a film having a thickness of 100 nm is at least 70%.

11. Electrode comprising a transparent electric conductor according to claim 1 in the form of a film.

12. Electrode according to claim 11, wherein the electrode is used in an electronic device selected from the group consisting of: photovoltaic devices; electrochromic devices; light-emitting devices; flat-panel display devices; image sensing devices.

13. Device comprising a transparent electric conductor according to claim 1 in the form of a film.

14. Process for manufacturing a transparent electric conductor, comprising forming on a surface, a film of Ti_{1-a-b}AlₐX_{b}O_{y}, where X is a dopant or a mixture of dopants selected from the group consisting of Nb, Ta, W, Mo, V, Cr, Fe, Zr, Co, Sn, Mn, Er, Ni, Cu, Zn and Sc, in such a way that a is in the range 0.01 to 0.50, and b is in the range 0.01 to 0.15.

15. Process for manufacturing a transparent electric conductor, comprising forming on a surface, a film of Ti₁₋ₐAlₐF_{c}O_{y-c}, in such a way that a is in the range 0.01 to 0.50, and c is in the range 0.01 to 0.10.

16. Process according to claim 14, wherein X is Nb, a is in the range 0.02 to 0.12, and b is in the range 0.03 to 0.12.

17. Process according to claim 14, wherein the temperature of the surface at the time of forming the film on the surface is room temperature.

18. Process according to claim 14 wherein the temperature of the surface at the time of forming the film on the surface is in the range 100° C. to 450° C.

19. Process according to claim 14 wherein, following the forming of the film, the process comprises annealing the film in a reducing atmosphere.

20. Process according to claim 19, wherein the reducing atmosphere contains H₂ and the annealing is performed at a temperature in the range 350° C. to 700° C.

21. Transparent electric conductor according to claim 4, wherein a is in the range 0.04 to 0.08, and b is in the range 0.05 to 0.12.

22. Transparent electric conductor according to claim 6, wherein the electrical resistivity of the transparent electric conductor is at most 3×10⁻³ Ωcm.

23. Transparent electric conductor according to claim 7, wherein the refractive index of the transparent electric conductor is at least 2.3 at 550 nm.

24. Transparent electric conductor according to claim 10, wherein the light transmittance, in the wavelength range 400 nm to 700 nm, of the transparent electric conductor in the form of a film having a thickness of 100 nm is at least 75%.

25. Electrode according to claim 12, wherein the electrode is used in an organic light-emitting diode device.

26. Device according to claim 13, wherein the device is selected from the group consisting of a photovoltaic device, an electrochromic device, a light-emitting device, a flat-panel display device, an image sensing device, an infrared-reflective glazing, an UV-reflective glazing, and an antistatic glazing.

27. Process according to claim 14, wherein the surface is a surface of a substrate.

28. Process according to claim 14, wherein a is in the range 0.02 to 0.15.

29. Process according to claim 28, wherein a is in the range 0.03 to 0.12.

30. Process according to claim 15, wherein the surface is a surface of a substrate.

31. Process according to claim 15, wherein a is in the range 0.02 to 0.15.

32. Process according to claim 31, wherein a is in the range 0.03 to 0.12.

33. Process according to claim 16, wherein a is in the range 0.04 to 0.08.

34. Process according to claim 16, wherein b is in the range 0.05 to 0.12.

35. Process according to claim 15, wherein the temperature of the surface at the time of forming the film on the surface is room temperature.

36. Process according to claim 15, wherein the temperature of the surface at the time of forming the film on the surface is in the range 100° C. to 450° C.

37. Process according to claim 15, wherein, following the forming of the film, the process comprises annealing the film in a reducing atmosphere.

38. Process according to claim 37, wherein the reducing atmosphere contains H₂ and the annealing is performed at a temperature in the range 350° C. to 700° C.
